(19) United States
(12) Patent Application Publication
(10) Pub. No.: US 2012/0027041 A1
(43) Pub. Date: Feb. 2, 2012

(54) WAVELENGTH VARIABLE LASER AND A MANUFACTURING METHOD THEREOF

(76) Inventor: Hiroyuki Yamazaki, Tokyo (JP)

(21) Appl. No.: 13/256,665

(22) PCT Filed: Mar. 8, 2010
(86) PCT No.: PCT/JP2010/053781

§ 371 Date: Sep. 15, 2011

(30) Foreign Application Priority Data
Mar. 16, 2009 (JP) 2009-063160

(51) Int. Cl. H01S 5/026; H01L 21/98

(52) U.S. Cl. 372/50.12; 438/23; 257/E21.705

(57) ABSTRACT

A wavelength variable laser includes: a substrate on which an optical coupler is formed as a planar optical waveguide; a DFB array part arranged on the substrate and having DFB laser elements respectively supply optical signals to the optical coupler; and an SOA part arranged on the substrate and having an SOA element configured to amplify an optical signal outputted from the optical coupler. The DFB array part and the SOA part are respectively formed in chips having a same lamination structure to each other. A wavelength variable laser and a modulator integrated wavelength variable laser with high yield ratio can be provided.

### TECHNICAL FIELD

The present invention relates to a structure of a wavelength variable laser and a manufacturing method thereof.

### BACKGROUND ART

The broadband age has come, and for the effective application of the optical fiber, the introduction of the WDM (Wavelength Division Multiplexing) transmission system by which a communication through a plurality of optical wavelengths has been progressed. Recently, the DWDM apparatus (Dense Wavelength Division Multiplexing apparatus) capable of transmitting with higher speed by multiplexing dozens of optical wavelengths is widely used. Along with this, an optical source corresponding to each optical wavelength is required for every WDM transmission system. Along with the higher multiplexing, the required number of optical sources is drastically increased. Further, in recent years, the investigation for bringing the ROADM (Reconfigurable optical add/drop multiplexers) which performs Add/Drop of any wavelengths at each node into commercial base has been progressed. By introducing the ROADM system, in addition to the enlargement of the transmission capacity caused by the wavelength multiplexing, it becomes possible to switch the optical paths by changing the wavelength, thereby the degree of freedom of the optical network is drastically enhanced.

As the optical source of the WDM transmission system, the DFB-LD (Distributed feedback laser diode) which oscillates in the single axis mode is widely used conventionally because of the usability and the reliability. In the DFB-LD, the diffraction grating with the depth of about 30 nm is formed on the whole area of the oscillator, and a stable single axis mode oscillation can be obtained with the wavelength corresponding to the double of the product of the period of the diffractive grating and the equivalent index of refraction. In the DFB-LD, a stable single-axis mode oscillation can be obtained. However, it is not possible to perform tuning covering a wide range of the oscillation wavelength. Therefore, the WDM transmission system is constructed by using products which are different from each other only in their wavelengths for every ITU grid generally. As a result, it is required to use different products for each wavelength, thereby the management cost of the stocks is increased and the surplus stocks for coping with troubles are needed. Further, if a normal DFB-LD is used in the ROADM in which the optical path is switched in accordance with the wavelength, its variable width is restricted into the wavelength range which can be varied by the temperature change (about 3 nm). Consequently, it becomes difficult to construct an optical network which has an advantage of the ROADM which actively use the wavelength resources.

For overcoming the above problems of the current DFB-LD and realizing a single axis mode oscillation in a wide wavelength range, researches of the wavelength variable laser are energetically performed. The wavelength variable laser is grossly classified into two types. In a first type, the wavelength variable mechanism is introduced in the same element with the laser oscillator. In a second type, the wavelength variable mechanism is provided outside the element. FIG. 1 shows a configuration of the DBR-LD (Distributed Bragg Reflector Laser Diode) being an example of the first type. In this type, the light emitting region and the distributed reflection region are arranged in the same element. FIG. 2 shows a configuration of the Sampled-Grating-DBR-LD being an example of the second type. The period of the diffractive grating periodically varies and the light emitting region is arranged in a place pinched with these diffractive gratings. FIG. 3 shows a configuration of the SSG (Super Structure Grating)-DBR-LD as another example of the second type.

In the past, the wavelength variation of the DBR-LD is restricted in a range up to about 10 nm. However, in the Sampled-Grating-DBR-LD proposed after that, by utilizing the vernier effect which is proper to this structure, the wavelength variable operation over 10 nm and the semi-continuous wavelength variable operation of 40 nm are realized.

In the wavelength variable optical source of the second type, it is possible to perform a wavelength variable operation by providing a diffractive grating outside the element as shown in FIG. 4 and by adjusting its angle, the distance and the like accurately.

In another proposed configuration, an optical oscillator is constructed by the PLC (Planar Lightwave Circuit), and a wavelength variable optical source is realized by directly mounting an LD or an SOA (Semiconductor Optical Amplifier) on the PLC. FIG. 5 shows a configuration which realizes a wavelength variable optical source by a combination of a ring oscillator and the SOA. A Characteristic of the ring oscillator formed by the PLC is in that the circumferences of the rings are slightly different from each other. Caused by this difference, the vernier effect occurs, thereby a variable wavelength operation in wide wavelength range is realized.

### CITATION LIST

### Non Patent Literature

H. Yamazaki et al., ECOC2004, post-deadline paper 4.2.4., 2004

### SUMMARY OF INVENTION

Though various kinds of wavelength variable lasers as mentioned above are proposed, many of them have a structure which requires complex controls, and the increasing complexity of the firmware for the laser control becomes a problem to be solved. For coping with this problem, a wavelength selection optical source in which an array DFB laser, a multi-mode interference optical coupler, and an SOA are integrated monolithically is proposed. FIG. 6 shows an example of the wavelength selection optical source described in NLTP 1. The array DFB lasers are arranged at the wavelength interval of about 3 nm, and the oscillation wavelength control within a range smaller than the interval is performed by changing the temperature of the element. However, also in this structure, a complex compound semiconductor process is required, so that a high yield ratio cannot be expected. Further, the resulting increase in cost is not ignorable.

A wavelength variable laser according to the present invention includes: a substrate on which an optical coupler is formed as a planar optical waveguide; a DFB (Distributed Feedback Laser Diode) array part arranged on the substrate and having a plurality of DFB laser elements respectively supply optical signals to the optical coupler; and an SOA (Semiconductor Optical Amplifier) part arranged on the substrate and having an SOA element configured to amplify an optical signal outputted from the optical coupler. The DFB array part and the SOA part are respectively formed in chips having a same lamination structure to each other.

A manufacturing method of a wavelength variable laser according to the present invention includes: forming an optical coupler on a substrate as a planar optical waveguide; arranging a DFB (Distributed Feedback Laser Diode) array having a plurality of DFB laser elements respectively supply optical signals to the optical coupler on the substrate; and arranging an SOA (Semiconductor Optical Amplifier) part having an SOA element configured to amplify an optical signal outputted from the optical coupler on the substrate. The DFB array part and the SOA part are respectively formed in chips having a same lamination structure to each other.

According to the present invention, a wavelength variable laser, and a modulator integrated wavelength variable laser can be realized with high yield ratio and without requiring a complex compound semiconductor manufacturing process.

### BRIEF DESCRIPTION OF DRAWINGS

The above objects, other objects, effects, and characteristics of the present invention will become clearer by the description of exemplary embodiments with reference to the accompanying drawings, in which;

FIG. 1 shows a configuration of the DBR-LD; FIG. 2 shows a configuration of the Sampled-Grating-DBR-LD;

FIG. 3 shows a configuration of the SSG-DBR-LD;

FIG. 4 shows a wavelength variable operation by a diffractive grating outside the element;

FIG. 5 shows a wavelength variable optical source being a combination of a ring oscillator and an SOA;

FIG. 6 shows an example of a wavelength selection optical source;

FIG. 7 shows a structural view of a wavelength variable laser;

FIG. 8 shows a structure in which a semiconductor Mach-Zehnder modulator is integrated on a wavelength variable laser;

FIG. 9 shows a manufacturing process of a wavelength variable laser;

FIG. 10 shows a manufacturing process of a wavelength variable laser;

FIG. 11 shows a manufacturing process of a wavelength variable laser;

FIG. 12 shows a manufacturing process of a wavelength variable laser; and

FIG. 13 shows a configuration of a wavelength variable laser.

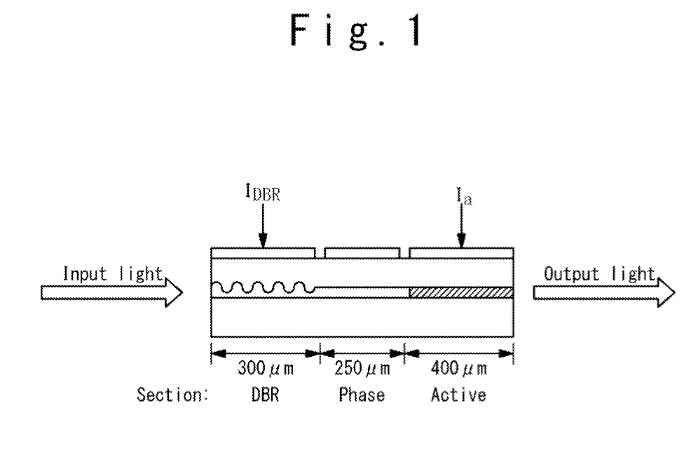

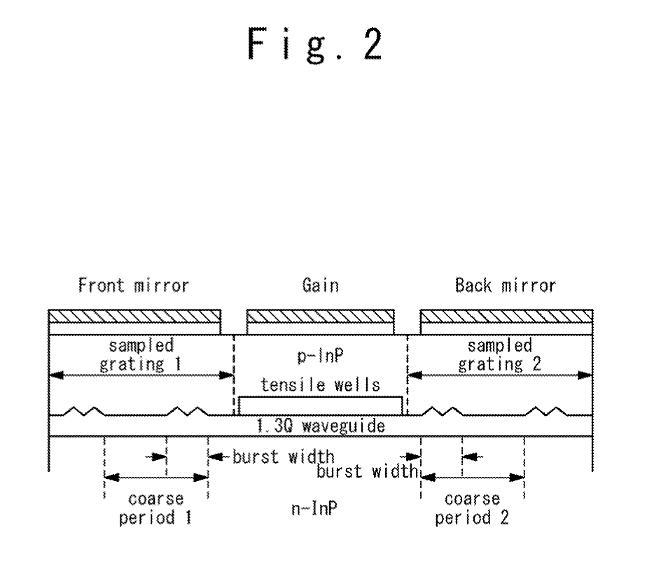

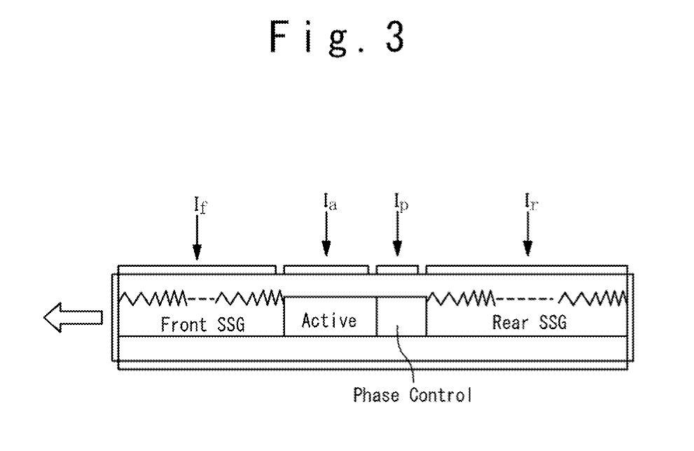

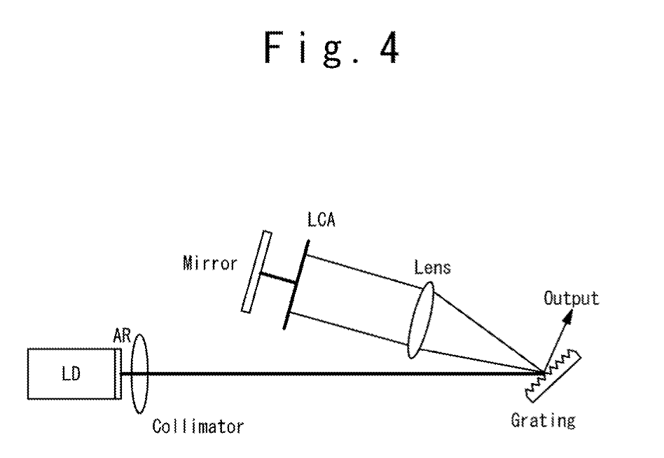

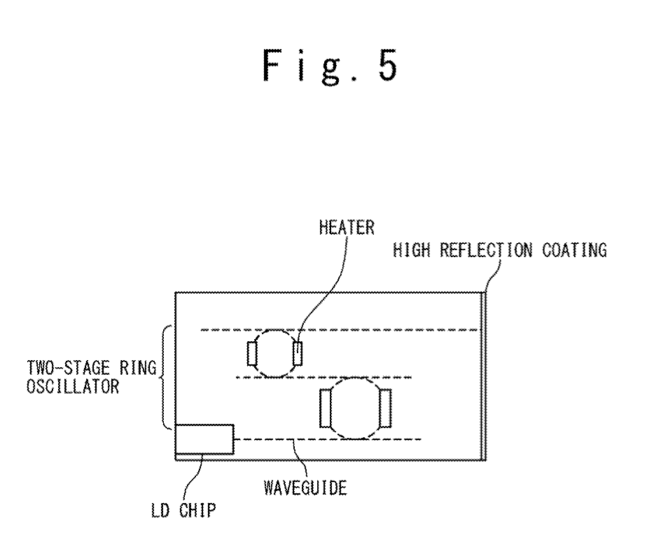

### DESCRIPTION OF EMBODIMENTS

In the following, an exemplary embodiment of the present invention is explained with reference to the drawings. In the present exemplary embodiment, a compound semiconductor element in which an array DFB and a semiconductor optical amplifier are integrated is formed. A wavelength variable laser is constructed by mounting this compound semiconductor element on a platform on which an optical coupler is formed. The mounting is performed. by a passive alignment using alignment marks.

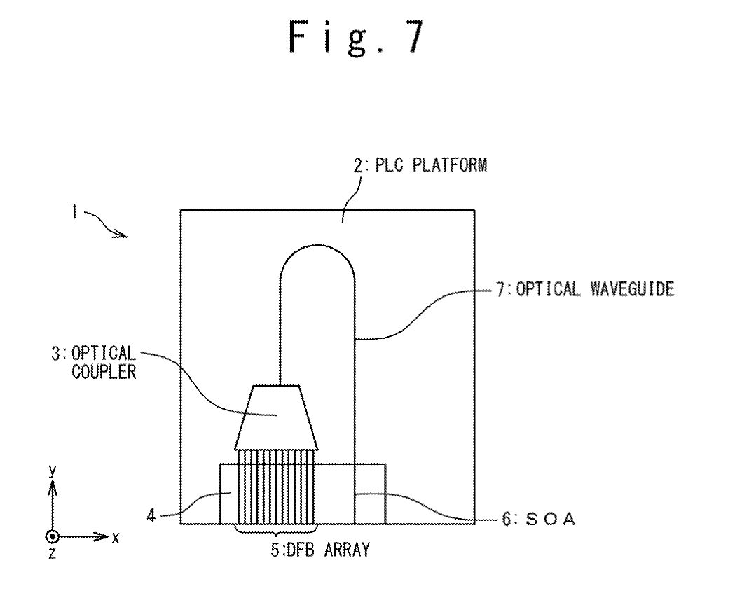

FIG. 7 is a plan view showing a configuration of a wavelength variable laser 1 according to the present exemplary embodiment. An optical waveguide 7 and an optical coupler 3 are formed on the PLC platform by planar optical waveguides. The optical coupler 3 guides the optical signal introduced from each of the plurality of optical waveguides arranged in an input side to optical waveguides 7 which are coupled to an output side.

A DFB array 5 and an SOA (Semiconductor Optical Amplifier) 6 are integrated on a same chip 4. The DFB array is formed on a first region of the chip 9. The DFB array 5 consists of a plurality of DFB laser elements whose oscillation wavelengths are different from each other. The optical waveguides of the respective DFB lasers are formed to be in parallel with each other and whose extending direction (propagation direction) of the optical axis is directed in the y-axis direction shown in the drawing. The SOA 6 is formed on a second region which is a traverse direction of the first region of the DFB array 5 on the chip 4, namely, is a position deviated in the x-axis direction shown in FIG. 7. The SOA 6 has an optical waveguide extending in the y-axis direction. The chip 4 has a terminal part which is in parallel with the x-axis at the output side of the DFB array 5. The terminal part of the output side of the DFB array 5 and the terminal part of the optical waveguide of the input side of the optical coupler 3 are coupled to each other at high accuracy. The optical waveguide 7 extends from the output terminal of the optical coupler in the positive y-axis direction, turns its direction by 180 degrees, on the PLC platform to direct to the negative y-axis direction. The output terminal of the optical waveguide 7 in the negative y-axis direction and the input terminal of the SOA 6 are coupled to each other in high accuracy.

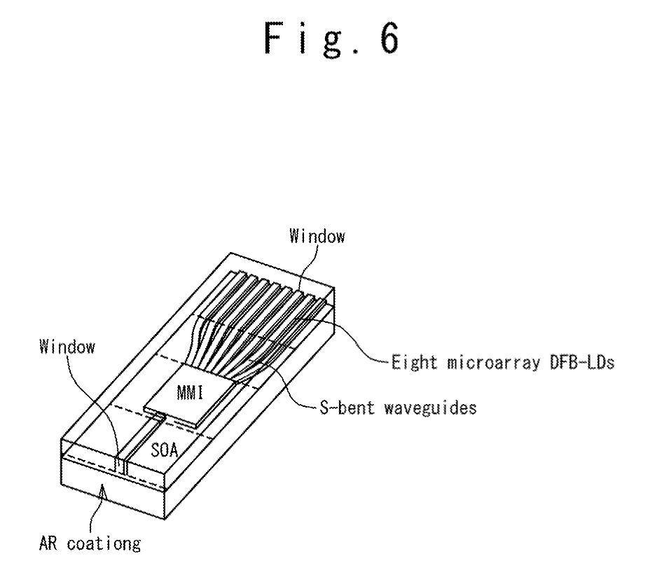

By manufacturing the DFB array 5 and the SOA 6 which compose the integrated optical source on the chip 4 in same processes in parallel, they are formed in the respective active layers having a same lamination structure and a same composition. In such an integrated optical source, the manufacturing process can be simplified compared with the integrated wavelength variable laser exemplified as a background technique, and it is possible to improve the yield ratio and reduce the cost. The wavelength variable operation can be performed in a similar principle as indicated in the example of FIG. 6. The laser light outputted from the DFB array 5 is coupled to the optical coupler 3, attenuated by 12 dB in principle, and coupled to the optical waveguide 7 of the output side. Further, the laser light coupled to the optical waveguide 7 is inputted to the SOA 6 formed on the same chip 4 to the DFB array 5, optically amplified or adjusted in the optical output thereof, and outputted.

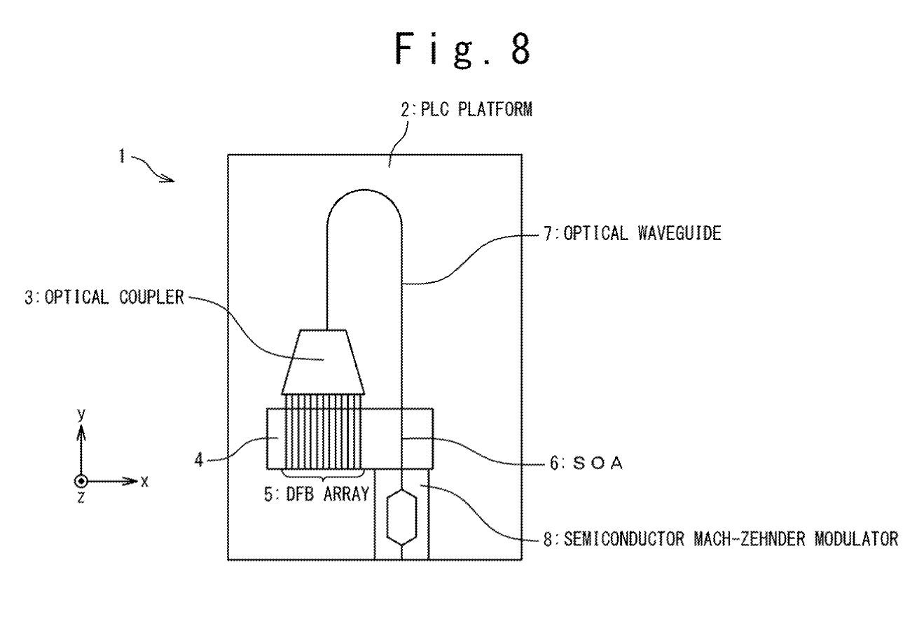

FIG. 8 shows the configuration in which a semiconductor Mach-Zehnder modulator 8 is integrated on the wavelength variable laser 1 of the present exemplary embodiment. The compound semiconductor chip 4 on which the DFB array 5 and the SOA 6 are integrated is mounted on the PLC platform 2 by passive alignment. Subsequently, the semiconductor Mach-Zehnder modulator 8 is mounted by passive alignment using an alignment mark, and the optical waveguide of the SOA 6 and the optical waveguide of the semiconductor Mach-Zehnder modulator 8 are optically coupled to each other at high accuracy. The intensity modulation is performed by applying an inverse voltage to one side arm of the semiconductor Mach-Zehnder modulator 8. Alternatively, the push-pull operation, by which the voltages applied to the both arms are varied, can be adopted.

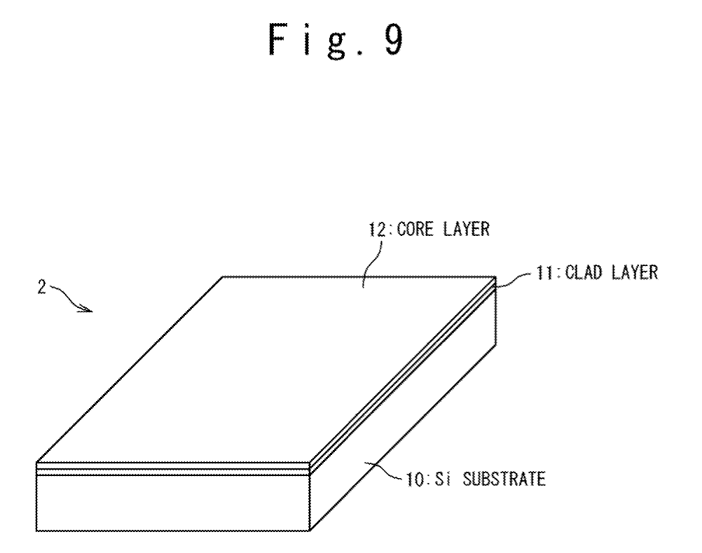

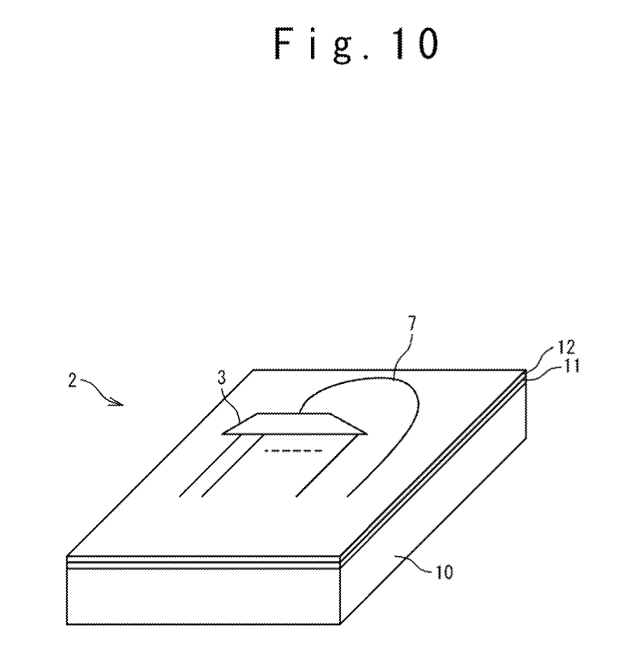

Next, with reference to FIGS. 9 to 12, the manufacturing method of the wavelength variable laser 1 according to the present exemplary embodiment is explained. FIG. 9 shows a first process. The Si substrate 10 is provided. The films of the clad layer 11 and the core layer 12 are formed on the Si substrate 10 by the CVD method or the like. Ge, N, B, P or the like is doped into the core layer, and their dopant amounts are adjusted so that the refractive index thereof becomes higher by about 6%. FIG. 10 shows a second process. The waveguide patterns including the optical coupler 3, the optical waveguide or the like are formed in the clad layer 11 and the core layer 12 by the photoresist process and the dry etching process.

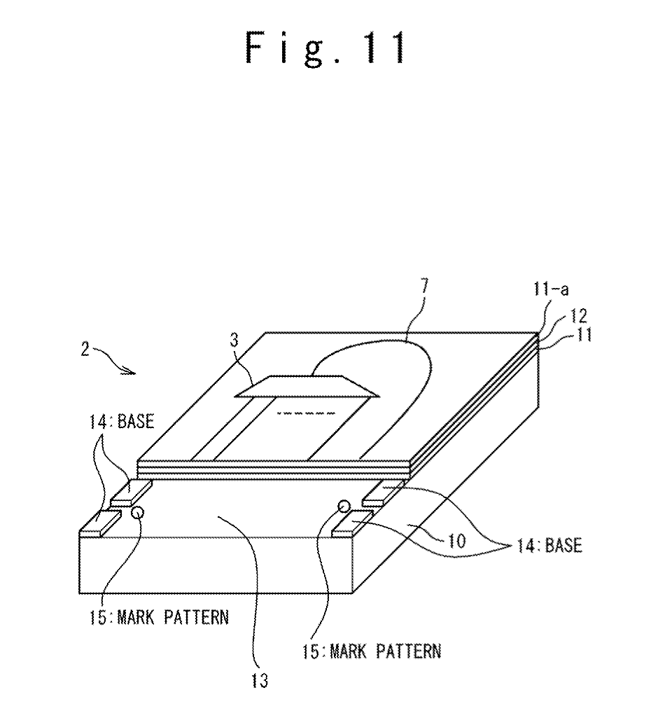

FIG. 11 shows a third process. The clad layer 11-a is formed on the core layer 12. After that, the step part 13 for installing the chip 4 is formed by grinding a predetermined region of the clad layer 11-a, the core layer 12, and the clad layer 11. The terminal part of the optical waveguide of the input side of the optical coupler 3 is exposed at the terminal part of the step part 13. A base 14 is formed at the step part 13 for the positioning in the direction vertical to the chip 4 accurately. Further in the step part 13, the mark patterns 15 for the passive alignment mounting are formed.

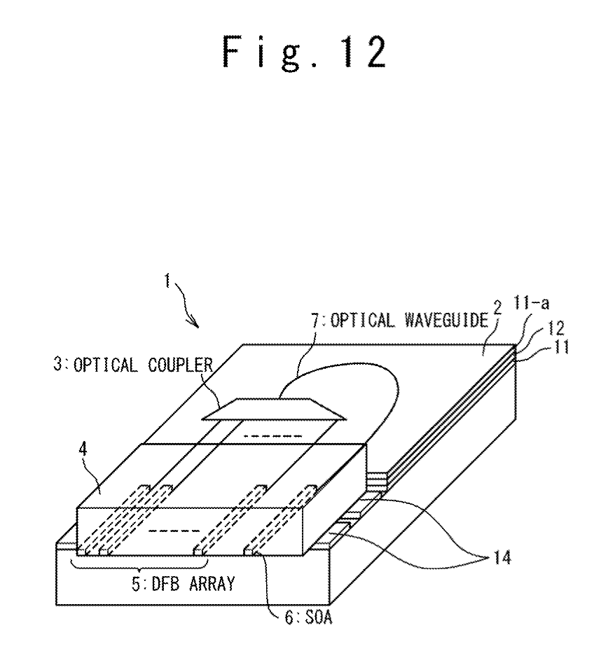

FIG. 12 shows a fourth process. In this process, the chip 4 is installed on the PLC platform 2. The manufacturing method of the chip 4 is explained firstly. On the n-InP substrate, diffractive grating having different periods is formed for wavelength selection by the EB (Electron Beam) or the dry etching. The width of the diffractive grating is 5 μm, and the interval between them is 10 μm. Subsequently, an n-clad layer and an active layer are formed in turn by the MOVPE (Metalorganic Vapor Phase Epitaxy) growth. After the forming of the oxide film pattern for forming the waveguide, the dry etching is performed. At this time, in the DFB array 5 part, the waveguide is formed on the part where the diffractive grating is formed. Further, the SOA 6 for amplifying and outputting the light is manufactured by forming a waveguide on a part where no diffractive grating is formed. After that, the selective growth is performed by using the oxide film which is used for the waveguide forming, and a pnpn thyristor structure for current confinement is formed on a side of the waveguide.

After removing the oxide film, the p-clad layer is made grown, and the mark pattern electrodes for passive alignment are formed. Further, the element manufacturing process is completed by forming electrodes for supplying electricity on both sides of the substrate. Gel is filled between the optical waveguide of the PLC platform 2 and the chip 4 for the refractive index matching. Associated with this, in the connection terminal surfaces of the chip 4 and the PLC platform 2, for achieving the non-reflection to the diffractive index of the gel, the terminal surface of the chip 4 is coated. On the opposite side of the chip 4 being the terminal surface of the light emitting side, the gel is not filled so that the non-reflection coating to the air is performed.

On the base 14 at the step part 13, the chip 4, on which the DFB array 5 and the SOA 6 which are arranged in the traverse direction are integrated, is mounted. The horizontal direction of the chip 4 is determined by passive alignment using the mark pattern 15 and the chip 4 is fixed on the base 14. By this position-determining, the optical waveguide 7 formed in the PLC platform 2 and the optical waveguides of the DFB array 5 and the SOA 6 are coupled in high accuracy.

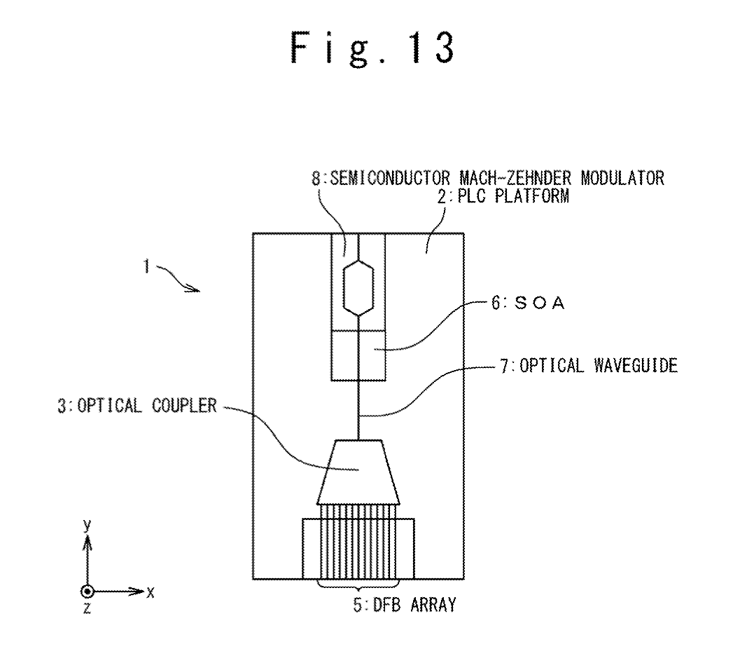

FIG. 13 shows a wave length variable laser according to another exemplary embodiment. In this exemplary embodiment, instead of the curved optical waveguide 7 in FIG. 7, a linear optical waveguide 7 is formed. An optical coupler 3 and a linear optical waveguide 7 are formed on the PLC platform 2. The DFB array 5 and the SOA 6 are formed in the chip in which the same laminated structure manufactured by same processes in parallel is formed. After that, by cutting and dividing the chip, a unit of the DFB array 5 and a unit of the SOA 6 which are formed in the same laminated structure are obtained. The DFB array 5, the SOA 6, and the semiconductor Mach-Zehnder modulator 8 are mounted on the PLC platform 2 by passive alignment.

The wavelength variable laser according to the exemplary embodiment shown in FIG. 13 has a characteristic, similarly to that shown in FIG. 7, that complex manufacturing processes can be avoided. For example, in the structure shown in FIG. 6, though the DFB laser array region (referred to as Eight Microarray DFB-LDs in the drawing) and the SOA are formed by material having same composition wavelength, it is required to form the MMI and the curved waveguide by material having different composition wavelength. Therefore the manufacturing process becomes complex and there is anxiety that the reproducibility of characteristics or yield ratio decreases. In the present exemplary embodiment, similarly to the case in FIG. 6, the DFB laser array and the SOA are formed by material having the same compound wavelength. However, the optical coupler for the waveguide and the wave integration is formed by silica material on the Si substrate. As a result, the manufacturing can be performed by a simple process so that a good productivity is expected.

In the above, the present invention is explained with reference to some exemplary embodiments. However, the present invention is not limited to the above exemplary embodiments, and various modifications can be applied to them. For example, it is possible to combine the above-explained exemplary embodiments.

This application is based upon and claims the benefit of priority from Japanese patent application No. 2009-063160, filed on Mar. 16, 2009, the disclosure of which is incorporated herein its entirety by reference.

1. A wavelength variable laser comprising:
a substrate on which an optical coupler is formed as a planar optical waveguide;
a DFB (Distributed Feedback Laser Diode) array part arranged on the substrate and having a plurality of DFB laser elements respectively supply optical signals to the optical coupler; and
an SOA (Semiconductor Optical Amplifier) part arranged on the substrate and having an SOA element configured to amplify an optical signal outputted from the optical coupler,
wherein the DFB array part and the SOA part are respectively formed in chips having a same lamination structure to each other.

2. The wavelength variable laser according to claim 1, wherein the DFB array part and the SOA array part are formed in a same chip.

3. The wavelength variable laser according to claim 2, wherein optical waveguides of the plurality of DFB laser elements are formed in a first region of the same chip in parallel to each other, and
an optical waveguide of the SOA element is formed in a second region placed on a direction orthogonal to a propagation direction of the optical waveguides of the plurality of waveguides from the first region and in parallel to the propagation direction.

4. The wavelength variable laser according to claim 1, wherein the DFB array part and the SOA array part are formed by dividing a same chip.

5. A manufacturing method of a wavelength variable laser comprising:
forming an optical coupler on a substrate as a planar optical waveguide;
arranging a DFB (Distributed Feedback Laser Diode) array having a plurality of DFB laser elements respectively supply optical signals to the optical coupler on the substrate; and
arranging an SOA (Semiconductor Optical Amplifier) part having an SOA element configured to amplify an optical signal outputted from the optical coupler on the substrate,
wherein the DFB array part and the SOA part are respectively formed in chips having a same lamination structure to each other.

6. The manufacturing method of a wavelength variable laser according to claim 5, wherein the DFB array part and the SOA array part are formed in a same chip.

7. The manufacturing method of a wavelength variable laser according to claim 6, wherein optical waveguides of the plurality of DFB laser elements are formed in a first region of the same chip in parallel to each other, and
an optical waveguide of the SOA element is formed in a second region placed on a direction orthogonal to a propagation direction of the optical waveguides of the plurality of waveguides from the first region and in parallel to the propagation direction.

8. The manufacturing method of a wavelength variable laser according to claim 6, wherein the DFB array part and the SOA array part are formed in a same chip, and
the manufacturing method further comprises:
dividing the same chip into a part having the DFB array part and a part having the SOA part.
